(19) United States
(12) Patent Application Publication
(10) Pub. No.: US 2025/0353133 A1
(43) Pub. Date: Nov. 20, 2025

(54) MANAGEMENT DEVICE, MANAGEMENT METHOD, AND WAFER MANUFACTURING SYSTEM

(71) Applicant: SUMCO Corporation, Tokyo (JP)

(72) Inventor: Yuji MIYAZAKI, Tokyo (JP)

(73) Assignee: SUMCO Corporation, Tokyo (JP)

(21) Appl. No.: 18/992,276

(22) PCT Filed: Apr. 6, 2023
(86) PCT No.: PCT/JP2023/014282

§ 371 Date: Jan. 8, 2025

(30) Foreign Application Priority Data
Jul. 28, 2022 (JP) 2022-120955

(51) Int. Cl. B24B 37/005

(52) U.S. Cl. CPC B24B 37/005

(57) ABSTRACT

A management device includes a control section which manages a plurality of wafer processing devices. The control section determines a wafer processing device to be assigned to process a given type of wafers from among the plurality of wafer processing devices, based on a distance between post-processing characteristics of wafers processed by each of the wafer processing devices and a center value of a standard for the given type of wafers.

### TECHNICAL FIELD

This disclosure relates to a management device for managing a wafer processing device, a management method, and a wafer manufacturing system including the wafer processing device.

### BACKGROUND

In a semiconductor wafer polishing device, there has conventionally been known a double-side polishing method for wafers that can control batch-to-batch variation in GBIR values of wafers after polishing (See, e.g., PTL 1, etc.).

### CITATION LIST

### Patent Literature

PTL 1: JP 2019-114708 A1

### SUMMARY

### Technical Problem

In recent years, as design rules in semiconductor devices have increasingly been detailed, the requirements for semiconductor wafer standards have become stricter. As a result, in promoting the improvement of wafer processing yield, problems began to be observed in cases where the yield difference between devices became significant, depending on the required standards.

Therefore, the purpose of the present disclosure is to propose a management device, a management method, and a wafer manufacturing system that can improve the wafer processing yield.

### Solution to Problem

One embodiment of the present disclosure that solves the above problem is as follows.
[1] A management device, wherein comprising a control section which manages a plurality of wafer processing devices, and the control section determines a wafer processing device to be assigned to process a given type of wafers from among the plurality of wafer processing devices, based on a distance between post-processing characteristics of wafers processed by each of the wafer processing devices and a center value of a standard for the given type of wafers.
[2] The management device according to [1] above, wherein the control section calculates, for each of the wafer processing devices, the post-processing characteristics that are closest to the center value of the standard for the given type of wafers as an optimal characteristics, and determines a wafer processing device to be assigned to process the wafers of a given type in order of the shortest distance between the optimal characteristics and the center value of the standard for the given type of wafers.
[3] The management device according to [2] above, wherein the control section selects, from among the post-processing characteristics when processing conditions of each of the wafer processing devices are changed, the post-processing characteristics that comes closest to the center value of the standard for the given type of wafers as the optimal characteristics.
[4] The management device according to [3] above, wherein the processing conditions are determined by each of the wafer processing devices performing an end point detection.
[5] The management device according to any one of [1] to [4] above, wherein the control section plots a point representing the post-processing characteristics of wafers on a graph whose origin is the center value of the standard for the given type of wafers, and calculates a distance between the plotted point and the origin of the graph.
[6] A method for managing a plurality of wafer processing devices, wherein the method includes determining a wafer processing device to be assigned to process a given type of wafers from among the plurality of wafer processing devices, based on a distance between post-processing characteristics of wafers processed by each of the wafer processing devices and a center value of a standard for the given type of wafers.
[7] A wafer manufacturing system, wherein comprising a management device as described in any one of claims 1 to 4, and a wafer processing device that is managed by the management device.

### Advantageous Effect

According to the management device, the management method, and the wafer manufacturing system in accordance with the present disclosure, the wafer processing yield can be improved.

### BRIEF DESCRIPTION OF THE DRAWINGS

In the accompanying drawings:

FIG. 1 is a block diagram illustrating an example configuration of a wafer manufacturing system in accordance with one embodiment of the present disclosure;

FIG. 2 is a top view of a double-side polishing device for wafers as a wafer processing device in accordance with one embodiment of the present disclosure;

FIG. 3 is a cross-sectional view taken along the line A-A in FIG. 2;

FIG. 4 is an illustration providing an example of the relationship between the shape of wafer surface, and the amount of unevenness and the outer circumferential flatness;

FIG. 5 is a graph providing an example of post-processing characteristics for wafer processing devices;

FIG. 6 is a graph providing an example of the relationship between post-processing characteristics of wafers processed by wafer processing devices and a standard;

FIG. 7 is an example of a map providing assignments of wafer processing devices; and

FIG. 8 is a flowchart providing an example procedure of a management method in accordance with one embodiment of the present disclosure.

### DETAILED DESCRIPTION

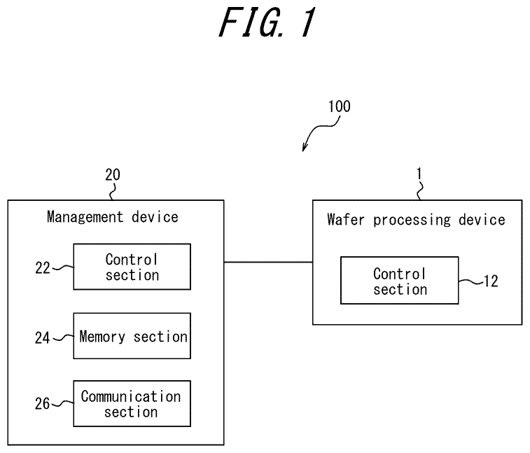

Hereinafter, a wafer manufacturing system 100 in accordance with one embodiment of the present disclosure will be described with reference to the drawings. As illustrated in FIG. 1, the wafer manufacturing system 100 comprises a wafer processing device 1 and a management device 20. The management device 20 manages the wafer processing device 1. The management device 20 may assign a process to be processed by the wafer processing device 1. The management device 20 may determine the processing conditions in the wafer processing device 1.

In this embodiment, the wafer processing device 1 is described as a double-side polishing device for wafers. The wafer processing device 1 is not limited to a polishing device, but may also be other processing devices such as a wire saw device.

### CONFIGURATION EXAMPLE OF WAFER PROCESSING DEVICE 1

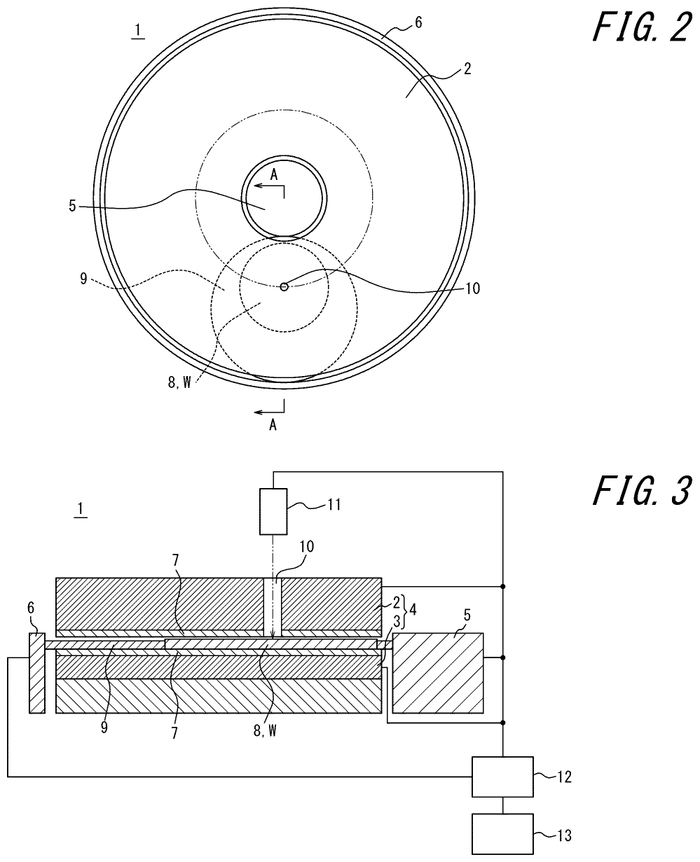

FIG. 2 is a top view of the wafer processing device 1 in accordance with one embodiment of the present disclosure. FIG. 3 is a cross-sectional view taken along the line A-A in FIG. 2. As illustrated in FIGS. 2 and 3, the wafer processing device 1 comprises a rotating surface plate 4 having an upper surface plate 2 and a lower surface plate 3 opposed thereto, a sun gear 5 provided at the center of rotation of the rotating surface plate 4, and an internal gear 6 in an annular shape provided around the outer circumference of the rotating surface plate 4. As illustrated in FIG. 3, polishing pads 7 are affixed to the opposing sides of the upper and lower rotating surface plates 4, i.e., the lower side, the polishing surface, of the upper surface plate 2, and the upper side, the polishing surface, of the lower surface plate 3, respectively.

The wafer processing device 1 comprises a plurality of carrier plates 9, which are provided between the upper surface plate 2 and the lower surface plate 3 and have one or more holes 8 for holding a workpiece W (wafer) to be processed. In FIG. 2, only one of the pluralities of carrier plates 9 is illustrated. Also, the number of the holes 8 may be one or more, e.g., three. The workpiece W may be held in the holes 8.

Assume that the wafer processing device 1 is a planetary gear type double-side polishing device that can make the carrier plate 9 perform planetary motion including orbital and rotational motion by rotating the sun gear 5 and the internal gear 6. By rotating the carrier plate 9 in planetary motion while supplying polishing slurry, and by rotating the upper surface plate 2 and the lower surface plate 3 relative to the carrier plate 9, the wafer processing device 1 can slide the polishing pads 7 affixed to the upper and lower rotating surface plates 4 and both sides of the workpiece W held in the holes 8 of the carrier plate 9 against each other, to simultaneously polish both sides of the workpiece W.

In the wafer processing device 1 according to this embodiment, the upper surface plate 2 has one or more holes 10 that penetrate from the upper surface of the upper surface plate 2 to the lower surface thereof, which is the polishing surface. That is, the holes 10 are provided in the upper surface plate 2. One hole 10 is disposed at a location that passes near the center of the workpiece W. The number of the holes 10 is not limited to one, but may be two or more. The holes 10 may be provided in the lower surface plate 3 as well as in the upper surface plate 2. One or more holes 10 may be provided in at least one of the upper surface plate 2 and the lower surface plate 3. The holes 10 may be arranged in multiple locations around the circumference of the upper surface plate 2 (on the dash-single-dotted line in FIG. 2). As illustrated in FIG. 3, the holes 10 may penetrate through to the polishing pad 7 affixed to the upper surface plate 2. In other words, the holes 10 may penetrate from the upper surface of the upper surface plate 2 to the lower surface of the polishing pad 7.

The wafer processing device 1 may be configured to measure the thickness of a workpiece W in real time through one or more holes 10 during double-side polishing on the workpiece W. Specifically, the wafer processing device 1 may comprise a workpiece thickness measuring device 11 at a position corresponding to the hole 10. In the example illustrated in FIG. 3, the workpiece thickness measuring device 11 is disposed above the upper surface plate 2. In this embodiment, assume that the workpiece thickness measuring device 11 is a wavelength-variable infrared laser device. The workpiece thickness measuring device 11 may, for example, comprise an optical unit that irradiates a laser beam onto the workpiece W, a detection unit that detects the laser beam reflected from the workpiece W, and a calculation unit that calculates the thickness of the workpiece W from the detected laser beam. The example workpiece thickness measuring device 11 can calculate the thickness of a workpiece W based on the difference in optical path length between the reflected laser light reflected on the front surface of the workpiece W and the reflected laser light on the back surface of the workpiece W. The workpiece thickness measuring device 11 may be any device capable of measuring the thickness of the workpiece W in real time, and is not limited to the device using an infrared laser as exemplified above.

The wafer processing device 1 in accordance with the present disclosure comprises a control section 12. The control section 12 is connected to the upper surface plate 2, the lower surface plate 3, the sun gear 5, the internal gear 6, and the workpiece thickness measuring device 11. The control section 12 controls each component of the wafer processing device 1.

The wafer processing device 1 may perform only one process to process the workpiece W, or it may perform two or more processes. The process of processing a workpiece W is also referred to as a processing process. The wafer processing device 1 controls the amount of wafer processing in each processing process by setting values for one or more setting items in each process. In other words, the value set for each setting item performed by the wafer processing device 1 identifies the processing operation of the wafer processing device 1. The values set for setting items are also referred to as setting values. That is, the processing volume for wafers in each processing process is controlled by changing the setting value of each setting item.

The setting items in the processing process performed by the wafer processing device 1 may include, for example, the polishing time of the workpiece W or the pressure at which the workpiece W is polished. In addition, the setting items may include various items such as the number of rotations of the upper surface plate 2 or the number of revolutions or rotations of the carrier plate 9.

The characteristics of a wafer change as a result of the wafer processing device 1 processing the wafer. The characteristics of a wafer are determined by the flatness of the front or back surface of the wafer, or the thickness of the wafer, etc. The characteristics of a wafer processed by the wafer processing device 1 are also referred to as post-processing characteristics.

When the wafer processing device 1 executes one processing process, a plurality of setting items in that process can affect the post-processing characteristics of the wafer in relation to each other. Also, when the wafer processing device 1 executes a plurality of processing processes, the setting items of each processing process can affect the post-processing characteristics of the wafer in relation to each other. Further, in the wafer manufacturing system 100, the setting items of the processing process executed by a plurality of wafer processing devices 1 can affect the post-processing characteristics of the wafer in relation to each other.

The wafer processing device 1 in accordance with this embodiment may further comprise a calculation section 13 that determines the timing to finish double-side polishing on the workpiece W during double-side polishing on the workpiece W. The calculation section 13 is connected to the control section 12. The calculation section 13 obtains a workpiece thickness data measured by the workpiece thickness measuring device 11 and determines the timing to finish double-sided polishing on the workpiece W. The control section 12 may terminate the processing operation of the workpiece W by the wafer processing device 1, at the timing determined by the calculation section 13. The determination of when to finish double-sided polishing on a workpiece W is also referred to as an endpoint detection. The calculation section 13 may determine the timing for completing double-sided polishing on the workpiece W based on a thickness of the workpiece W as described above, or it may determine the timing as the timing after a predetermined time has elapsed from the timing when a thickness of the workpiece W meets the predetermined condition. The post-processing characteristics of a wafer processed by the wafer processing device 1 can be adjusted by setting the time to continue further polishing from the timing when the endpoint is detected, as the processing conditions of the device 1.

### EXAMPLE CONFIGURATION OF MANAGEMENT DEVICE 20

The management device 20 has a control section 22. The control section 22 determines the parameters that specify the processing conditions of the wafer processing device 1 and outputs them to the wafer processing device 1. The control section 22 is configured to be able to communicate with the control section 12 of the wafer processing device 1. The control section 22 may include at least one processor. The processor may execute programs that implement various functions of the control section 22. The processor may be realized as a single integrated circuit. The integrated circuits are also referred to as ICs. The processors may be realized as a plurality of communicatively connected integrated circuits and discrete circuits. The processors may be realized based on various other known technologies.

The management device 20 may further comprise a memory section 24. The memory section 24 stores, for example, measurement results of wafer characteristics measured by an external wafer measurement device. The memory section 24 may include an electromagnetic storage medium such as a magnetic disk, or it may include a memory such as a semiconductor memory or a magnetic memory. The memory section 24 may include a non-transitory computer readable medium. The memory section 24 stores various types of information and programs executed by the control section 22. The memory section 24 may function as a work memory for the control section 22. At least a portion of the memory section 24 may be configured as a separate entity from the control section 22.

The management device 20 may further comprise a communication section 26 that transmits and receives data to and from the wafer processing device 1 or an external device. The communication section 26 may be connected to other devices for communication via a network. The communication section 26 may be connected to other devices for wired or wireless communication. The communication section 26 may comprise a communication module that connects to a network or other device. The communication module may comprise a communication interface such as LAN (Local Area Network). The communication module may comprise a communication interface for contactless communication such as infrared communication or Near Field communication (NFC). The communication module may implement communication using various communication methods, such as 4G or 5G. The communication method implemented by the communication section 26 is not limited to the above example and may include various other methods.

### Operation Example of Management Device 20

The wafer processing device 1 processes a wafer (workpiece W). The post-processing characteristics of a wafer are determined by processing conditions applied to the wafer. If the wafer manufacturing system 100 comprises a plurality of wafer processing devices 1 that perform the same processing, each of the wafers is processed by one of the wafer processing devices 1. That is, the processing conditions applied to the wafer include information for selecting a wafer processing device 1 to be applied to process the wafer from among the plurality of wafer processing devices 1. The processing conditions applied to the wafer include setting items for when the selected wafer processing device 1 processes the wafer.

When a given type of wafer is manufactured using the wafer processing device 1, the post-processing characteristics of the wafer must meet the standard for that type. In this wafer manufacturing system 100 in accordance with this embodiment, the control section 22 of the management device 20 determines processing conditions to be applied to the wafer so that the post-processing characteristics of the wafer meet the standards for a given type. The control section 22 outputs the processing conditions to the wafer processing device 1 selected as the processing conditions. The wafer processing device 1 processes the wafer based on the processing conditions.

### <Indicator Representing Wafer Characteristics>

An indicator representing the post-processing characteristics of a wafer may include, for example, an indicator representing wafer flatness. An indicator representing the wafer flatness is also referred to as a flatness index.

The flatness index of a wafer may include, for example, the amount of unevenness. The amount of unevenness is an indicator of the degree of unevenness in the overall shape of the wafer. The amount of unevenness is obtained by approximating the relationship between the wafer thickness and the wafer radial position on the wafer with an even function, and then calculating the difference between the even function value at the wafer center and the even function value at the wafer outer periphery. Here, the wafer is defined as convex if the calculated value is positive; and the wafer is defined as concave if the calculated value is negative. The magnitude of the absolute value of the calculated value then represents the degree of unevenness. The flatness index of a wafer may include, for example, an outer circumferential flatness. The outer circumferential flatness is a measure of the flatness of the wafer periphery. The outer circumferential flatness may be expressed, for example, by ESFQD (Edge Site flatness Front reference least sQuare Deviation). The ESFQD evaluates the distance between the reference surface in the site and the wafer surface at each site after dividing the wafer periphery into multiple sites. The smaller the maximum absolute value of ESFQD, the higher the flatness of the wafer.

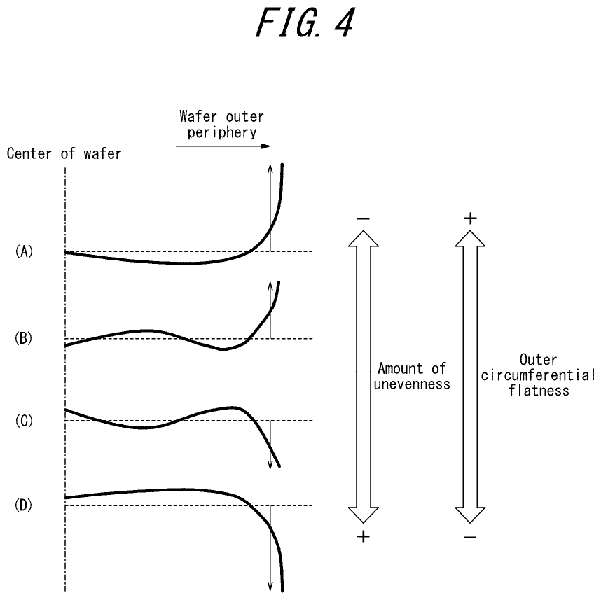

Assume that, in the wafer manufacturing system 100 in accordance with this embodiment, the indicators of the post-processing characteristics of a wafer shall include the amount of unevenness and the outer circumferential flatness. The amount of unevenness is also referred to as the first index. The outer circumferential flatness is also referred to as the second index. As mentioned above, the amount of unevenness represents the unevenness of the wafer surface. The outer circumferential flatness represents the flatness of the wafer periphery. As illustrated in FIG. 4, the unevenness of the surface of a polished wafer correlate with the shape of the wafer periphery. Specifically, FIG. 4 illustrates four different wafer surface topographies (A) through (D). In FIG. 4, the dashed line represents the position of the surface when the wafer is flattened (reference plane). The solid line represents the cross- sectional shape of the wafer surface. In FIG. 4, the left side of the dashed line representing the reference plane is located at the center of the wafer, and the right side thereof is located at the wafer periphery.

The topographies (A) and (B) in FIG. 4 represent a shape in which the wafer surface is below the reference plane (the surface shape is concave) and the wafer periphery is higher than the reference plane. In comparing (A) and (B) in FIG. 4, the concave shape of the wafer surface is deeper in (A) than in (B). The shape of the wafer periphery is higher in (A) than in (B). That is, there is a relationship that the deeper the concave shape of the wafer surface, the higher the wafer periphery. The state where the wafer periphery is high is also referred to as RollUp.

Assume that, when the shape of the wafer surface is concave as illustrated in (A) and (B) in FIG. 4, the amount of unevenness is a negative value. Also, assume that, when the wafer periphery has a shape that is higher than the reference plane as illustrated in (A) and (B) in FIG. 4, the outer circumferential flatness is a positive value. In comparing (A) and (B) in FIG. 4, the amount of unevenness is smaller in (A) than in (B). The absolute value of the amount of unevenness is greater in (A) than in (B). The outer circumferential flatness is greater in (A) than in (B). That is, there is a relationship that the smaller the amount of unevenness, the greater the outer circumferential flatness.

The topographies (C) and (D) in FIG. 4 represent a shape in which the wafer surface is above the reference plane (the surface shape is convex) and the wafer periphery is lower than the reference plane. In comparing (C) and (D) in FIG. 4, the convex shape of the wafer surface is higher in (D) than in (C). The wafer periphery is lower in (D) than in (C). That is, there is a relationship that the higher the convex shape of the wafer surface, the lower the wafer periphery. The state where the wafer periphery is low is also referred to as RollOff.

Assume that, when the shape of the wafer surface is convex as illustrated in (C) and (D) in FIG. 4, the amount of unevenness is a positive value. Also, assume that, when the wafer periphery has a shape that is lower than the reference plane as illustrated in (C) and (D) in FIG. 4, the outer circumferential flatness is a negative value. In comparing (C) and (D) in FIG. 4, the amount of unevenness is greater in (D) than in (C). The outer circumferential flatness is smaller in (D) than in (C). The absolute value of the outer circumferential flatness is greater in (D) than in (C). That is, there is a relationship that the larger the amount of unevenness, the smaller the outer circumferential flatness.

To summarize what has been mentioned above with reference to FIG. 4, in a wafer processed with the wafer processing device 1 in accordance with this embodiment, the uneven shape of the wafer surface correlates with the height of the wafer periphery. In addition, the amount of unevenness correlates with the outer circumferential flatness. Arrows are provided on the right side of each waveform from (A) to (D) in FIG. 4, to provide the trend of changes in values of the amount of unevenness and the outer circumferential flatness. The values of the amount of unevenness and the outer circumferential flatness tend to vary inversely. In this embodiment, it is assumed that the longer the polishing time by the wafer processing device 1, the larger the value of unevenness and the smaller the value of the outer circumferential flatness.

The flatness index of a wafer is not limited to the above examples and may include GBIR (Global Backside Ideal Range), ESFQR (Edge flatness metric, Sector based, Front surface referenced, least sQuares fit reference plane, Range of the data within a sector), or various other metrics such as Bump. The indicator representing the post-processing characteristics of a wafer is not limited to the flatness index and may include a variety of other indicators, such as an indicator representing the thickness of a wafer.

### <Determination of Wafer Processing Device 1 to be Applied for Processing>

As mentioned above, the control section 22 of the management device 20 determines processing conditions so that post-processing characteristics of a wafer meet the standard for a given type. In this embodiment, the control section 22 determines the processing conditions so that the amount of unevenness and the outer circumferential flatness, among indicators representing the post-processing characteristics of a wafer, meet the standard.

When the wafer manufacturing system 100 comprises a plurality of wafer processing devices 1, the post-processing characteristics of wafers will vary even if the same processing conditions are set for each of the wafer processing devices 1 to process the wafers. Considering the variation in the post-processing characteristics of the wafers processed by each of the wafer processing devices 1, the control section 22 must adjust the processing conditions for each of the wafer processing devices 1 so that the post-processing characteristics of the wafers processed by each of the wafer processing devices 1 meet the standard for a given type. However, by adjusting the processing conditions so that the amount of unevenness and the outer circumferential flatness meet the standard, other indicators may change.

The control section 22 may select, from among the plurality of wafer processing devices 1, a wafer processing device 1 that ensures that the post-processing characteristics of wafers meet the standard for a given type without adjusting the processing conditions. The control section 22 may apply the selected wafer processing device 1 to process the wafers. The post-processing characteristics of the wafers processed by the selected wafer processing device 1, are likely to meet the standard for a given type. In addition, the control section 22 may judge, for each of the wafer processing devices 1, whether the post-processing characteristics of wafers meet the standard for a given type without adjusting the processing conditions. The control section 22 may apply the wafer processing device 1, which has been judged to meet the standard, to process the wafers. The post-processing characteristics of the wafers processed by a wafer processing device 1 that has been judged to meet the standard for a given type without adjusting the processing conditions, are likely to meet the standard for a given type. By making it easier for the post-processing characteristics of wafers to meet the standard for a given type, the wafer processing yield is improved.

In other words, the control section 22 may evaluate the ease of meeting the standard as a result of the processing by the wafer processing device 1. The control section 22 may apply the highly rated wafer processing device 1 to process wafers. Even in this way, the post-processing characteristics of wafers are likely to meet the standard for a given type. As a result, the wafer processing yield is improved.

Specifically, the control section 22 selects a wafer processing device 1 in which the post-processing characteristics of wafers meet the standard for a given type without adjusting the processing conditions, based on an actual data of the post-processing characteristics of the wafers processed by each of the wafer processing devices 1. In addition, the control section 22 judges whether the post-processing characteristics of wafers meet the standard for a given type without adjusting the processing conditions with respect to each of the wafer processing devices 1, based on an actual data of the post-processing characteristics of the wafers processed by each of the wafer processing devices 1. The control section 22 may evaluate the probability that the post-processing characteristics of wafers processed by each of the wafer processing devices 1 meet the standard, based on an actual data of the post-processing characteristics of the wafers processed by each of the wafer processing devices 1. The control section 22 may determine the wafer processing device 1 to be applied to process the given type of wafers by the selection, determination or evaluation.

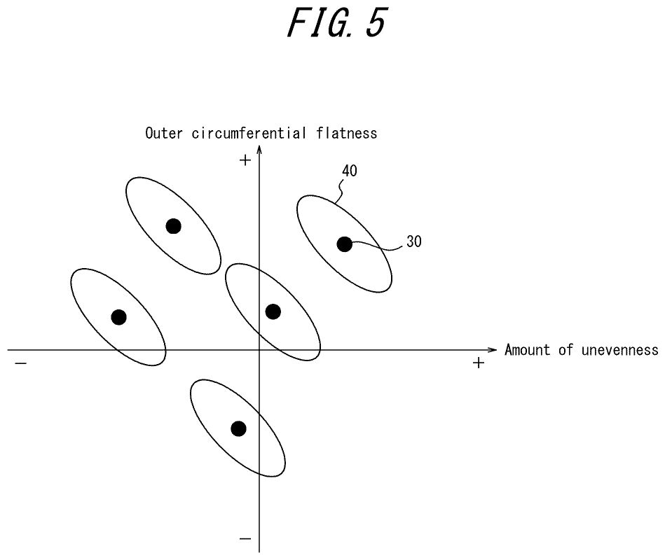

The control section 22 may determine the wafer processing device 1 to be applied to process a given type of wafers, based on a data representing the relationship between the amount of unevenness and the outer circumferential flatness as illustrated in FIG. 5, as an actual data on the post-processing characteristics of wafers. In the graph in FIG. 5, the horizontal axis corresponds to the amount of unevenness. The sign of the value of the amount of unevenness is assumed to be positive (+) on the right side and negative (−) on the left side. The vertical axis corresponds to the outer circumferential flatness. The sign of the outer circumferential flatness value is assumed to be positive (+) on the upper side and negative (−) on the lower side. At the intersection of the horizontal and vertical axes, the values of the amount of unevenness and the outer circumferential flatness are assumed to be zero.

The points 30 represented by solid (black) circles in the graph in FIG. 5 represent the average values in the amount of unevenness and the outer circumferential flatness of a plurality of wafers processed under the specified processing conditions in each of the wafer processing devices 1. The areas 40, represented by the boundary of ellipses surrounding each of the points 30, represent the range of variations in the amount of unevenness and the outer circumferential flatness of the plurality of wafers processed by each of the wafer processing devices 1. The areas 40 are calculated based on the standard deviation of the values of the amount of unevenness and the outer circumferential flatness of the plurality of wafers processed under the specified processing conditions in each of the wafer processing devices 1. Since the outer circumferential flatness tends to become − as the amount of unevenness becomes +, the area 40 has a shape with a major axis extending in the direction from the upper left to the lower right in the graph.

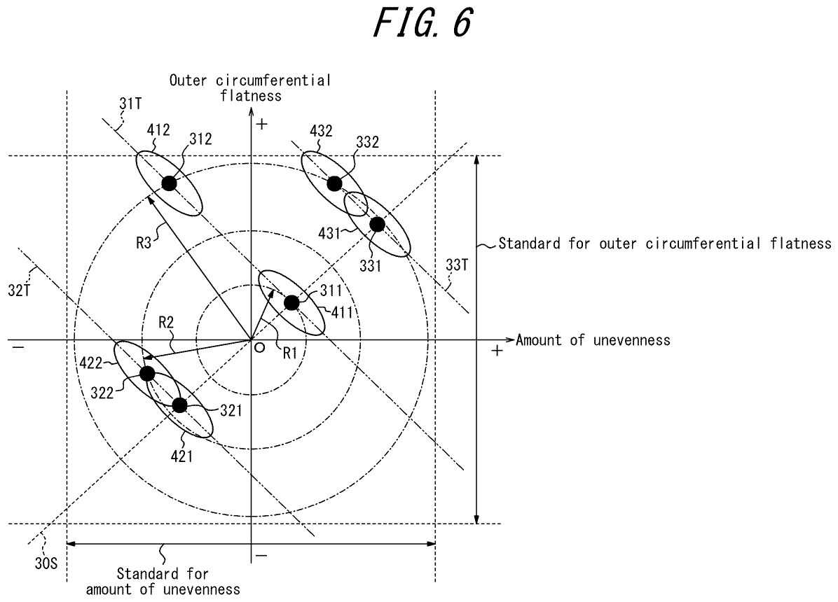

When manufacturing a given type of wafers, the post-processing characteristics of the wafers processed by the wafer processing device 1 must meet the standard. As illustrated in the graph in FIG. 6, assuming that the standard regarding the amount of unevenness and the outer circumferential flatness, for example, is set as the standard that the post-processing characteristics of a given type of wafers should meet. In FIG. 6, the horizontal axis represents the amount of unevenness. The vertical axis represents the outer circumferential flatness. The two dashed lines along the vertical axis represent the upper and lower limits of the standard for the amount of unevenness. The two dashed lines along the horizontal axis represent the upper and lower limits of the standard for the outer circumferential flatness. In other words, the standard that the post-processing characteristics of a given type of wafers should meet is represented as a rectangular range enclosed by the two dashed lines vertically and horizontally, respectively.

The post-processing characteristics of wafers are represented by the mean value and the range of variation, as described above. Let us assume that the average value of the post-processing characteristics of wafers processed by a certain wafer processing device 1 is represented by a point 312 and the range of variation is represented by an area 412. This wafer processing device 1 shall be referred to as the first processing device. The post-processing characteristics of the wafers processed by the first processing device may not meet the standard if the outer circumferential flatness varies towards the positive side (+), as the area 412 extends beyond the upper limit of the standard for the outer circumferential flatness.

Also, let us assume that the average value of the post-processing characteristics of wafers processed by a certain wafer processing device 1 is represented by a point 322, and the range of variation is represented by an area 422. This wafer processing device 1 shall be referred to as the second processing device. The post-processing characteristics of the wafers processed by the second processing device can meet the standard even considering the variations in the amount of unevenness and the outer circumferential flatness, since the area 422 is within the standard.

Here, let us assume that the variations in the post-processing characteristics of wafers processed by each of the wafer processing devices 1 is the same. In this case, the closer the average value of the post-processing characteristics of the wafers processed by the wafer processing device 1 is to the center of the standard, the more likely the post-processing characteristics of the wafers processed by that wafer processing device 1 will meet the standard, even taking variations into account. As an indicator that represents the average value of the post-processing characteristics of wafers is close to the center of the standard, in the graph in FIG. 6, the distance between the point representing the average value of the post-processing characteristics of the wafers and the origin O representing the center value of the standard can be calculated. A short distance between the point representing the average value of the post-processing characteristics of wafers and the origin O representing the central value of the standard means that the average value of the post-processing characteristics of the wafers is close to the central value of the standard.

In the graph in FIG. 6, the horizontal scale representing the amount of unevenness and the vertical scale representing the outer circumferential flatness are each assumed to be normalized so that the width of the standard for the amount of unevenness is equal to the width of the standard for the outer circumferential flatness. In this case, the distance is calculated as the square root of the sum of: the square of the amount of unevenness; and the square of the outer circumferential flatness. In other words, the distance can be calculated as the length of a two-dimensional vector whose elements are the respective values of the amount of unevenness and the outer circumferential flatness representing the post-processing characteristics, in a two-dimensional space whose origin is a point representing the center value of the standard.

The aspects in which the distance is calculated are not limited to this example. The graph representing the post-processing characteristics of wafers may have a coordinate system in which the widths of the two standards are normalized to be equal, as illustrated in FIG. 6, or it may have a coordinate system in which the widths of the two standards are different. Regardless of the ratio of the display of the width of the standard in the graph, the distance may be calculated by weighting the difference between the amount of unevenness and the central value of the standard, and the difference between the outer circumferential flatness and the central value of the standard, respectively. If the post-processing characteristics are represented by only one type of indicator, the distance can be calculated as the absolute value of the difference between the center of the standard for that indicator and the value of that indicator. If “n” is a natural number greater than or equal to 2 and the post-processing characteristics are represented by n types of indicators, the distance can be calculated as the length of an n-dimensional vector whose elements are the values of each of the n types of indicators representing the post-processing characteristics in n-dimensional space with the point representing the center of the standard at the origin.

If the post-processing characteristics are represented by n types of indicators, the graph has an axis corresponding to each of the n types of indicators. For example, if the number of indicators identifying the post-processing characteristics is n, the graph has n axes. The control section 22 may actually generate and display the graph, or it may generate the graph virtually as an internal process.

The point 312, which represents the average value of the post- processing characteristics of wafers processed by the first processing device, is located on a circle drawn by a dash-single-dotted line whose center is at the origin O and whose radius is R3. That is, the distance: from the origin O which represents the center value of the standard for the given type of wafers; to the point 312 which represents the average value of the post-processing characteristics of the wafers processed by the first processing device, is expressed as R3. Also, the point 322, which represents the average value of the post-processing characteristics of wafers processed by the second processing device, is located on the circle drawn by a dash-single-dotted line whose center is at the origin O and whose radius is R2. That is, the distance: from the origin O which represents the center value of the standard for the given type of wafers; to the point 322 which represents the average value of the post-processing characteristics of the wafers processed by the second processing device, is expressed as R2.

In FIG. 6, R3 is longer than R2. In this case, the distance from the origin O to the point 322 representing the average value of the post-processing characteristics of the wafers processed by the second processing device is shorter than the distance from the origin O to the point 312 representing the average value of the post-processing characteristics of the wafers processed by the first processing device.

Assuming that the processing conditions of the first and second processing devices remain the same, the average value of the post-processing characteristics of the wafers processed by the first processing device and the average value of the post-processing characteristics of the wafers processed by the second processing device both remain the same. Therefore, if the candidates for the wafer processing device 1 to be used to processes a given type of wafers are the first processing device and the second processing device only, under the assumption that the processing conditions are not changed, the control section 22 judges that the post-processing characteristics of the wafers processed by the second processing device are more likely to meet the standard than those of the wafers processed by the first processing device, and determines the second processing device as the wafer processing device 1 that processes the given type of wafers.

However, the processing conditions of the first or second processing device can be changed. For example, processing time and other conditions can be changed as the processing conditions. The processing conditions can be changed manually. If the wafer processing device 1 comprises a calculation unit 13, the processing conditions can be changed automatically by the calculation unit 13 detecting the end point. By changing the processing conditions, the average value of the post-processing characteristics of the wafers processed by each device can be adjusted.

When the processing conditions of the wafer processing device 1 are changed to various conditions, the set of points representing the post-processing characteristics of wafers processed by the wafer processing device 1 can form a predetermined trajectory in the graph representing the post-processing characteristics. The post-processing characteristics of wafers processed by changing the processing conditions to various conditions may be obtained by: actually setting the processing conditions to various conditions on the wafer processing device 1, and measuring the post-processing characteristics of the wafers processed under each condition. The post-processing characteristics of the wafers processed by changing the processing conditions to various conditions may be obtained: by calculating the post-processing characteristics of the wafers processed under various virtual processing conditions on the wafer processing device 1 by simulation.

The predetermined trajectory of the first processing device is represented as a trajectory 31T, which is depicted by the dash-double-dotted line in the graph in FIG. 6. The trajectory 31T includes the point 312. The average value of the post-processing characteristics of the wafers processed by the first processing device can be adjusted to the value represented by a point located on the trajectory 31T by adjusting the processing conditions. Also, the predetermined trajectory of the second processing device is represented as a trajectory 32T, which is depicted by the dash-double-dotted line in the graph in FIG. 6. The trajectory 32T includes the point 322. The average value of the post-processing characteristics of the wafers processed by the second processing device can be adjusted to the value represented by a point located on the trajectory 32T by adjusting the processing conditions.

The point representing the average value of the post-processing characteristics of the wafers processed by the wafer processing device 1 can be brought closer to the origin O by changing the processing conditions. The processing conditions of the first processing device can be adjusted so that the average value of the post-processing characteristics of the wafers processed by the first processing device will be the value represented by the point 311 closest to the origin O among each point on the trajectory 31T. The range of variation in the post-processing characteristics of the wafers processed by the first processing device with adjusted processing conditions is represented as an area 411. Also, the processing conditions of the second processing device can be adjusted so that the average value of the post-processing characteristics of the wafers processed by the second processing device will be the value represented by the point 321 closest to the origin O among each point on the trajectory 32T. The range of variation in the post-processing characteristics of the wafers processed by the second processing device with adjusted processing conditions is represented as an area 421.

The point 311, which represents the average value of the post-processing characteristics of the wafers processed by the first processing device with adjusted processing conditions, is located on the circle drawn with a dash-single-dotted line, whose center is at the origin O and whose radius is R1. That is, the distance from the origin O, which represents the center value of the standard for the given type of wafers, to the point 311, which represents the average value of the post-processing characteristics of the wafers processed by the first processing device with adjusted processing conditions, is expressed as R1. On the other hand, the point 321, which represents the average value of the post-processing characteristics of the wafers processed by the second processing device with adjusted processing conditions, is located outside the circle drawn with a dash-single-dotted line, whose center is at the origin O and whose radius is R1. That is, the distance from the origin O, which represents the center value of the standard for the given type of wafers, to the point 311, which represents the average value of the post-processing characteristics of the wafers processed by the second processing device with adjusted processing conditions, has a value greater than R1. In this case, the distance from the origin O to the point 321 is shorter than the distance from the origin O to the point 311. Therefore, if the candidates for the wafer processing devices 1 to be used to process the wafers of a given variety are the first and second processing devices only, the control section 22 judges that the post-processing characteristics of the wafers processed by the first processing device with adjusted processing conditions are more likely to meet the standard than those of the wafers processed by the second processing device, even after considering the variation in the post-processing characteristics, and determines the first processing device as the wafer processing device 1 for processing the given type of wafers.

Suppose that the average value of the post-processing characteristics of wafers processed by a certain wafer processing device 1 is represented by a point 332 and the range of variation is represented by an area 432. This wafer processing device 1 shall be referred to as the third processing device. The point 332, which represents the average value of the post-processing characteristics of the wafers processed by the third processing device, is located on the circle drawn with a dash-single-dotted line, whose center is at the origin O and whose radius is R3. That is, the distance from the origin O, which represents the center value of the standard for the given type of wafers, to the point 312, which represents the average value of the post-processing characteristics of the wafers processed by the third processing device, is expressed as R3.

The distance from the origin O to the point 332, which represents the average value of the post-processing characteristics of the wafers processed by the third processing device, is the same as the distance from the origin O to the point 312, which represents the average value of the post-processing characteristics of the wafers processed by the first processing device. Therefore, if the processing conditions of the first and third processing devices are not changed, the control section 22 considers the first and third processing devices to have the same performance as the wafer processing device 1 that processes the given type of wafers.

Here, the predetermined trajectory of the third processing device is represented as a trajectory 33T, which is drawn as a dash-double-dotted line on the graph in FIG. 6. The trajectory 33T includes a point 332. The average value of the post-processing characteristics of the wafers processed by the third processing device can be adjusted to the value represented by the point located on the trajectory 33T by adjusting the processing conditions. The range of variation in the post-processing characteristics of the wafers processed by the third processing device with adjusted processing conditions is represented as an area 431. The point 331, which represents the average value of the post-processing characteristics of the wafers processed by the third processing device with adjusted processing conditions, is located outside the circle drawn with a dash-single-dotted line, whose center is at the origin O and whose radius is R1. That is, the distance from the origin O, which represents the center value of the standard for the given type of wafers, to the point 331, which represents the average value of the post-processing characteristics of the wafers processed by the third processing device with adjusted processing conditions, has a value greater than R1. In this case, the distance from the origin O to the point 311 is shorter than the distance from the origin O to the point 331. Therefore, the control section 22 determines that the post-processing characteristics of the wafers processed by the first processing device with adjusted processing conditions are more likely to meet the standards than those of the wafers processed by the third processing device, even after considering the variation in the post-processing characteristics, and determines the first processing device as the wafer processing device 1 for processing the given type of wafers.

The trajectories 31T and 32T are represented as straight lines in FIG. 6, but could also be represented as curves. Also, the trajectories 31T and 32T extend toward the upper left and lower right in FIG. 6, but they are not limited to the example in FIG. 6 and may extend toward the lower left and upper right, or in the left-right or up-down directions. The trajectories 31T and 32T may be straight lines extending in different directions, or they may be different curves.

The processing conditions of each of the wafer processing devices 1 used when processing a given type of wafers can be adjusted so that the point representing the post-processing characteristics of the wafers is closest to the origin O. The control section 22 calculates, for each of the wafer processing devices 1, the shortest distance between the point representing the post-processing characteristics of the wafers, which can be achieved when the given type of wafers are processed under various processing conditions, and the origin O. The shorter the shortest distance calculated for the wafer processing device 1 when it processes a given type of wafers, the more suitable the wafer processing device 1 is for processing the given type of wafers. In other words, the calculated shortest distance represents the suitability of the wafer processing device 1 for processing the given type of wafers. The minimum distance that can be achieved when the wafer processing device 1 processes a given type of wafers is also referred to as the suitability of the wafer processing device 1 for the given type.

The post-processing characteristics of the wafers when it is adjusted to be closest to the origin O are the optimal post-processing characteristics when each of the wafer processing devices 1 processes the given type of wafers, and also referred to as optimal characteristics. The control section 22 may select, from among the post-processing characteristics when the processing conditions of each of the wafer processing devices 1 are changed, the post-processing characteristics that comes closest to the center value of the standard for the given type of wafers, as the optimal characteristics. The points representing the optimal characteristics when each of the wafer processing devices 1 processes the given type of wafers are located on the line 30S, which is drawn as a dashed line in the graph in FIG. 6. Conversely, the line 30S, which represents the optimal characteristics, is drawn as a set of points representing the optimal characteristics when each of the wafer processing devices 1 processes the given type of wafers. The line 30S, which represents the optimal characteristic, is represented in FIG. 6 as a straight line extending toward the lower left and upper right, but it is not limited to this, and may be represented as a straight line extending in various directions or as a curve.

The control section 22 adjusts, for each of the wafer processing devices 1, the processing conditions so that the point representing the post-processing characteristics of wafers come closest to the origin O to obtain the optimal characteristics when processing the given type of wafers. The control section 22 may plot the points, for each of the wafer processing devices 1, representing the optimal characteristics when processing the given type of wafers on a graph such as the one provided in FIG. 6, and generate a line 30S representing the optimal characteristics. The control section 22 may rank the points on the line 30S representing the optimal characteristics in order from closest to the origin O. The control section 22 assigns a higher rank to the points that are closer to the origin O. The control section 22 judges that the wafer processing device 1 corresponding to the point with a high rank has a high suitability for processing the given type of wafers.

To be more specific, in the example in FIG. 6, the point 311 represents the optimal characteristics when the first processing device processes the given type of wafers. Also, the point 321 represents the optimal characteristics when the second processing device processes the given type of wafers. The point 311 is closer to the origin O than the point 321. Therefore, the control section 22 assigns a higher rank to the point 311 than to the point 321. As a result, the control section 22 judges that the first processing device corresponding to the point 311 has a higher suitability for processing the given type of wafers than the second processing device corresponding to the point 321.

In addition, the point 331 represents the optimal characteristics when the third processing device processes the given type of wafers. The point 331 is further from the origin O than the points 311 and 321. Therefore, the control section 22 assigns a lower priority to the point 331 than to the points 311 and 321. As a result, the third processing device corresponding to the point 331 is judged to be less suitable for processing the given type of wafers than the first processing device corresponding to the point 311 and the second processing device corresponding to the point 321.

The control section 22 may rank the first processing device first, the second processing device second, and the third processing device third in terms of suitability for processing the given type of wafers. If the number of the wafer processing devices 1 required to process the given type of wafers is fixed, the control section 22 may select the required number of the wafer processing devices 1 in order, starting with the wafer processing device 1 that corresponds to the highest-ranked point. The control section 22 may determine the selected required number of the wafer processing devices 1 as the wafer processing devices 1 that process the given type of wafers. In the example in FIG. 6, if the required number of the devices is 1, the control section 22 determines only the first processing device, which is ranked first in terms of suitability for processing the given type of wafers, as the wafer processing device 1 for processing the given type of wafers. If the required number of the devices is two, the control section 22 determines the first processing device, which is ranked first in terms of suitability for processing the given type of wafers, and the second processing device, which is ranked second in terms of the same, as the wafer processing devices 1 for processing the given type of wafers.

As mentioned above, the control section 22 can determine a wafer processing device 1 that processes a given type of wafers. Specifically, the control section 22 obtains a post-processing characteristics of the wafers processed when various processing conditions are set virtually or actually for each of the wafer processing devices 1. The control section 22 calculates, for each of the wafer processing devices 1, the distance between the average value of the post-processing characteristics of the wafers processed when the various processing conditions are set and the center value of the standards that the processing conditions for the given type of wafers should satisfy. The control section 22 calculates, for each of the wafer processing devices 1, the minimum distance that can be achieved when processing the given type of wafers by setting various processing conditions. The shorter the minimum distance calculated for each of the wafer processing devices 1, the more suitable each of the wafer processing devices 1 is for processing the given type of wafers. The control section 22 ranks the suitability of each of the wafer processing devices 1 for processing the given type of wafers, using the minimum distance calculated for each of the wafer processing devices 1 as an indicator. The control section 22 selects a wafer processing device 1 from the plurality of wafer processing devices 1 in order of suitability for processing the given type of wafers, and determines the wafer processing device 1 that processes the given type of wafers. In this way, the control section 22 can assign a highly suitable wafer processing device 1 depending on the type of standards that the processing characteristics of the given type of wafers must meet, taking into account the individual differences of each of the wafer processing devices 1. As a result, the quality of the wafers can be improved.

<Assignment of Wafer Processing Device 1 when Manufacturing Multiple Types>

In the wafer manufacturing system 100, multiple types of wafers may be manufactured. For example, let's say that the first, second, and third types of wafers are manufactured. In this case, in the wafer manufacturing system 100, each of the plurality of wafer processing devices 1 is assigned to manufacture each type of the wafers. The control section 22 assigns each of the wafer processing devices 1 to the processing of each type of the wafers.

The post-processing characteristics of wafers processed by a wafer processing device 1 can be changed depending on the state of the wafer processing device 1. The control section 22 may change the assignment of each of the wafer processing devices 1 based on the change in the post-processing characteristics of the wafers processed by the wafer processing device 1.

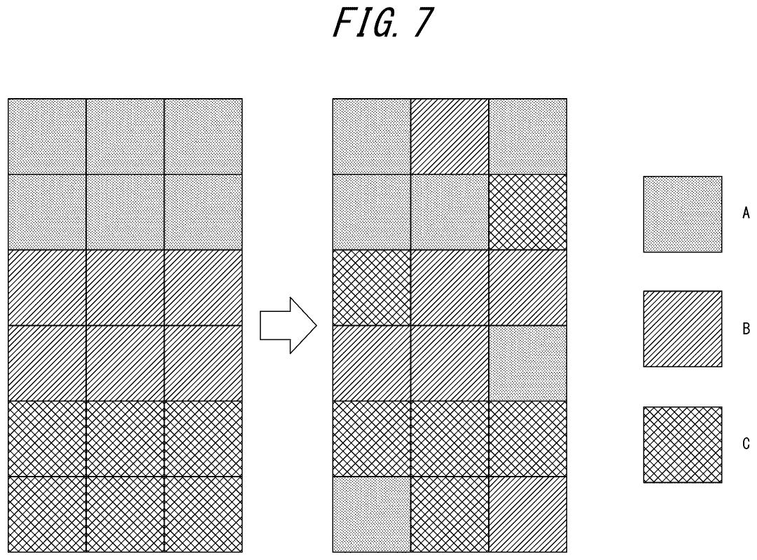

As illustrated in FIG. 7, let's assume that the assignment of each of the wafer processing devices 1 is represented as a map. The map on the left and the map on the right each represents the assignment of each of the wafer processing devices 1 at different points in time. The eighteen cells on the map correspond to the eighteen wafer processing devices 1 included in the wafer manufacturing system 100. The cells represented by the shaded hatchings (A) correspond to the wafer processing devices 1, which are assigned to manufacture the first type of wafers. The cells represented by the hatchings with diagonal lines sloping to the right (B) correspond to the wafer processing devices 1, which are assigned to manufacture the second type of wafers. The cells represented by the diagonal hatchings (C) correspond to the wafer processing devices 1, which are assigned to manufacture the third type of wafers.

The control section 22 changes the assignment of each of the wafer processing devices 1 to manufacture each type of wafers, in accordance with the change in the post-processing characteristics of the wafers processed by each of the wafer processing devices 1. Specifically, the control section 22 may generate a graph with points plotted to represent the post-processing characteristics of the first, second, and third types of wafers. The origin of each graph represents the center value of the standard for each type of wafers. The control section 22 may plot points, on the graph for each type, representing the post-processing characteristics of the wafers processed by each of the wafer processing devices 1. The control section 22 may plot points, on the graph for each type, representing the optimal characteristics when each of the wafer processing devices 1 processes each type of wafers. The control section 22 may generate, on the graph for each type, a line corresponding to the line 30S, in FIG. 6, representing the optimal characteristics.

The control section 22 calculates, on the graph for each type, the distance between the origin and the point representing the optimal characteristics when each of the wafer processing devices 1 processes each type of wafers. The control section 22 ranks each point in order of shortest distance. The ranking assigned to each point corresponds to the ranking of the suitability of each of the wafer processing devices 1 for processing each type of wafers. The control section 22 assigns the number of wafer processing devices 1 required to process each type of wafers, starting with the wafer processing device 1 that is most suitable for processing each type of wafers.

As illustrated in FIG. 7, when the wafer processing devices 1 are assigned to process the first, second, and third types of wafers, the control section 22 may rank the processing suitability of the wafer processing devices 1 for each type of the wafers. In the example in FIG. 7, the number of the wafer processing devices 1 required for processing each type is 6. The control section 22 may assign the wafer processing device 1, which has the first ranking in terms of suitability for processing the first type, to process the first type; the wafer processing device 1, which has the first ranking in terms of suitability for processing the second type, to process the second type; and the wafer processing device 1, which has the first ranking in terms of suitability for processing the third type, to process the third type. The control section 22 reorder the ranking of the processing suitability of the remaining wafer processing devices 1 for each type of wafers, and may assign the wafer processing device 1, which has the first ranking in terms of suitability for processing the first type, to process the first type; the wafer processing device 1, which has the first ranking in terms of suitability for processing the second type, to process the second type; and the wafer processing device 1, which has the first ranking in terms of suitability for processing the third type, to process the third type. The control section 22 may repeat the ranking of processing suitability and the assignment for processing each type until the number of wafer processing devices 1 assigned to the processing of each type reaches 6.

The control section 22 may assign two or more wafer processing devices 1 together in order of processing suitability for each type. The control section 22 may assign the first six wafer processing devices 1 in order of suitability for processing the first type, assign the next six wafer processing devices 1 in order of suitability for processing the second type, and assign the remaining six wafer processing devices 1 to processing the third type.

As a result of the operations described above, the control section 22 changes the assignment from the one illustrated in the map on the left in FIG. 7 to the one illustrated in the map on the right. Specifically, the control section 22 changes the assignment of one of the six wafer processing devices 1 assigned to the first type to the second type, and changes the assignment of one of the same to the third type. Also, the control section 22 changes the assignment of one of the six wafer processing devices 1 assigned to the second type to the first type, and changes the assignment of one of the same to the third type. In addition, the control section 22 changes the assignment of one of the six wafer processing devices 1 assigned to the third type to the first type, and changes the assignment of one of the same to the second type.

### <Operation Based on Processing Results>

The wafer processing devices 1 are applied to processing wafers, thereby newly processing the wafers. The control section 22 of the management device 20 may obtain the post-processing characteristics of the wafers newly processed by the wafer processing devices 1.

The control section 22 may adjust the processing time of the wafer processing devices 1 based on the post-processing characteristics of the newly processed wafers. The control section 22 may increase the processing time of the wafer processing device 1 when the amount of unevenness of the newly processed wafers is small or the outer circumferential flatness of the same is large. The control section 22 may shorten the processing time of the wafer processing devices 1 when the amount of unevenness of the newly processed wafers is large or the outer circumferential flatness of the same is small. In this way, it becomes easier for the post-processing characteristics of the wafers to meet the standard. As a result, the wafer processing yield can be improved.

The control section 22 may update the data representing the relationship between at least two indicators based on the post-processing characteristics of the wafers newly processed by the wafer processing devices 1. The control section 22 may re-evaluate the processing suitability of the wafer processing devices 1 based on the updated data. In this way, the state of the wafer processing devices 1 can be reflected in the evaluation results. As a result, the wafer processing yield can be improved.

### EXAMPLE OF MANAGEMENT PROCEDURE

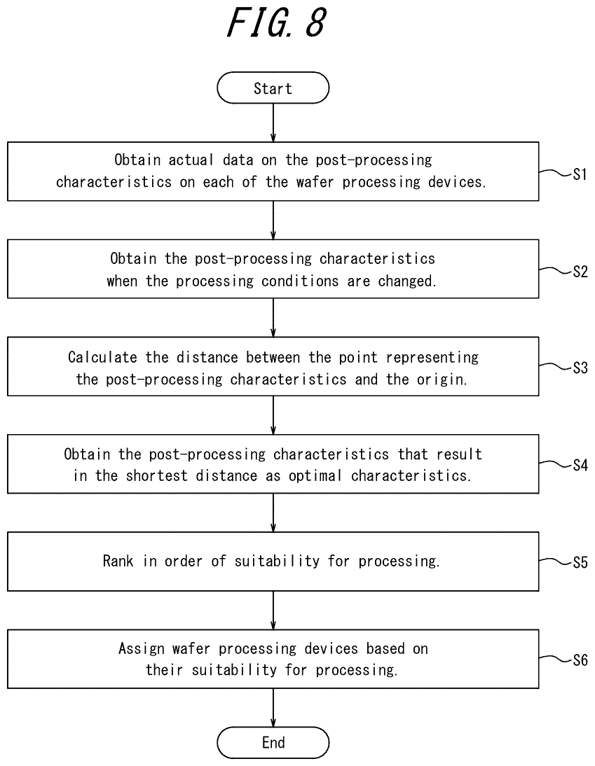

The control section 22 of the management device 20 may manage the wafer processing devices 1 by executing a management method that includes the procedures in the flowchart illustrated in FIG. 8. The management method may be realized as a management program that is executed by the control section 22.

The control section 22 obtains actual data on the post-processing characteristics of the wafers processed by each of the wafer processing devices 1 (step S1). The control section 22 obtains the post-processing characteristics of the wafers processed when the processing conditions are changed to various conditions in the wafer processing device 1 (step S2).

The control section 22 calculates the distance between the point representing the post-processing characteristics plotted on a graph whose origin is the center value of the standard for the given type of wafers, and the origin of the graph (step S3). The control section 22 sets the processing conditions so that the distance between the point representing the post- processing characteristics and the origin is minimized for each of the wafer processing devices 1, and obtains the post-processing characteristics that result in the shortest distance between the point representing the post-processing characteristics for the given type of wafers and the origin as the optimal characteristics (step S4). The control section 22 ranks each of the wafer processing devices 1 in order of suitability for processing the given type of wafers, based on the obtained optimal characteristics (step S5).

The control section 22 assigns in order the wafer processing devices 1, which have been ranked highly in terms of suitability for processing, to process the given type of wafers. In other words, the control section 22 assigns the wafer processing device 1 based on the ranking of processing suitability (step S6). The control section 22 ends the execution of the procedures in the flowchart in FIG. 8 after executing the procedures in Step S6. After executing the procedure in Step S6, the control section 22 may return to the procedure in Step S1 and assign the wafer processing devices 1 to process wafers of other types. The control section 22 may perform the assignment of the wafer processing devices 1 for processing wafers of each of the multiple types in parallel.

As described above, in the wafer manufacturing system 100 of this embodiment, the control section 22 of the management device 20 manages a plurality of wafer processing devices 1. The control section 22 calculates the distance between the post-processing characteristics of the wafers processed by each of the wafer processing devices 1 and the center value of the standard for a given type of wafers. The control section 22 determines a wafer processing device 1 to be assigned to process the given type of wafers, from among the plurality of wafer processing devices, based on the distance calculated for each of the wafer processing device 1. The control section 22 calculates the optimal characteristics for each of the wafer processing devices 1 based on the actual data of the post-processing characteristics of the wafers, and may assign the wafer processing devices 1 in order of the optimal characteristics being close to the center value of the standard for the wafers of a give type. In this way, it becomes easier for the post-processing characteristics of wafers to meet the standard. In addition, even when a plurality of indicators that are in a trade-off relationship, such as the amount of unevenness and the outer circumferential flatness, are specified as a standard, it becomes easier for the post-processing characteristics of wafers to meet the standard. As a result, the wafer processing yield in the wafer manufacturing system 100 can be improved.

The embodiments of the present disclosure have been described based on various drawings and examples, but it should be noted that a person skilled in the art can make various modifications or alterations based on the present disclosure. Therefore, it should be noted that these modifications or alterations are included within the scope of the present disclosure. For example, the functions contained in each component or each step, etc. can be rearranged so that they do not contradict logically, and it is possible to combine a plurality of components or steps, etc. into one or split them into a plurality of components or steps, etc. Although we have mainly been explaining the embodiments of this disclosure in terms of devices, the embodiments of the present disclosure can also be realized as a method that includes steps executed by each component of the device. The embodiments of the present disclosure can also be realized as methods, programs, or storage media that record programs, which are executed by the processor provided to the device. It is to be understood that these are also encompassed within the scope of the present disclosure.

The graphs included in this disclosure are schematic. The scale, etc. do not necessarily match the actual ones.

### INDUSTRIAL APPLICABILITY

According to the embodiments of this disclosure, the wafer processing yield can be improved.

### REFERENCE SIGNS LIST

100 Wafer manufacturing system
1 Wafer processing device
2 Upper surface plate
3 Lower surface plate
4 Rotating surface plate
5 Sun gear
6 Internal gear
7 Polishing pad
8 Hole
9 Carrier plate
10 Hole
11 Workpiece thickness measuring device
12 Control section
13 Calculation section
W Workpiece (wafer)
20 Management device
22 Control section
24 Memory section
26 Communication section
30, 311, 312, 321, 322, 331, 332: Points indicating post-processing characteristics
30S Line of optimal characteristics
31T, 32T, 33T Trajectory
40, 411, 412, 421, 422, 431, 432: Area
R1, R2, R3: Radius of concentric circles centered on the origin

1. A management device, wherein
comprising a control section which manages a plurality of wafer processing devices, and
the control section determines a wafer processing device to be assigned to process a given type of wafers from among the plurality of wafer processing devices, based on a distance between post-processing characteristics of wafers processed by each of the wafer processing devices and a center value of a standard for the given type of wafers.

2. The management device according to claim 1, wherein the control section calculates, for each of the wafer processing devices, the post-processing characteristics that are closest to the center value of the standard for the given type of wafers as an optimal characteristics, and determines a wafer processing device to be assigned to process the given type of wafers in order of the shortest distance between the optimal characteristics and the center value of the standard for the given type of wafers.

3. The management device according to claim 2, wherein the control section selects, from among the post-processing characteristics when processing conditions of each of the wafer processing devices are changed, the post-processing characteristics that comes closest to the center value of the standard for the given type of wafers as the optimal characteristics.

4. The management device according to claim 3, wherein the processing conditions are determined by each of the wafer processing devices performing an end point detection.

5. The management device according to claim 1, wherein the control section plots a point representing the post-processing characteristics of wafers on a graph whose origin is the center value of the standard for the given type of wafers, and calculates a distance between the plotted point and the origin of the graph.

6. A method for managing a plurality of wafer processing devices, wherein
the method includes determining a wafer processing device to be assigned to process a given type of wafers from among the plurality of wafer processing devices, based on a distance between post-processing characteristics of wafers processed by each of the wafer processing devices and a center value of a standard for the given type of wafers.

7. A wafer manufacturing system, wherein comprising a management device as described in claim 1, and a wafer processing device that is managed by the management device.
